(19) United States
(12) Patent Application Publication
(10) Pub. No.: US 2015/0311210 A1
(43) Pub. Date: Oct. 29, 2015

(54) SEMICONDUCTOR DEVICE MANUFACTURING METHOD AND SEMICONDUCTOR DEVICE

(71) Applicant: PS5 LUXCO S.A.R.L., L-2121Luxembourg (LU)

(72) Inventor: Shigeru Sugioka, Tokyo (JP)

(21) Appl. No.: 14/439,074

(22) PCT Filed: Oct. 23, 2013
(86) PCT No.: PCT/JP2013/078700

§ 371 Date: Apr. 28, 2015

(30) Foreign Application Priority Data
Nov. 2, 2012 (JP) 2012-242314

(51) Int. Cl. H01L 27/108; H01L 21/311; H01L 21/02; H01L 49/02

(52) U.S. Cl. CPC H01L 27/10814; H01L 27/10852; H01L 28/90; H01L 21/31111; H01L 21/0217; H01L 21/02274; H01L 21/02164

(57) ABSTRACT

A stopper film, a sacrifice film, and a beam configuration material film are formed by laminating the films in this order on a semiconductor substrate. A cylinder hole that penetrates the stopper film, the sacrifice film, and the beam configuration material film is formed, and a lower electrode that covers the inner surface of the cylinder hole is formed. The beam configuration material film is patterned so as to form a beam that is connected to at least a part of the outer circumferential surface of the lower electrode, thereby exposing a part of the sacrifice film. The sacrifice film is removed by wet etching, and a hollow is formed in the surface of the beam, said hollow being deeper than a hollow formed in the surface of the stopper film.

### TECHNICAL FIELD

The present invention relates to a method for manufacturing a semiconductor device, and in particular relates to a method for manufacturing a semiconductor device having a structure that supports a crown-shaped lower electrode with a beam.

### BACKGROUND OF THE INVENTION

A dynamic random access memory (DRAM) which is one type of semiconductor device uses a capacitor as a storage element. The area occupied by the capacitor has tended to become smaller in order to bring about increases in capacity and reductions in size of the DRAM.

This reduction in the area occupied by the capacitor leads to a reduction in the capacity of the capacitor and this reduction in the capacity of the capacitor may lead to a malfunction of the DRAM. Accordingly, in order to avoid a reduction in the capacity of the capacitor, the shape of a lower electrode thereof is made into a crown shape (or pillar shape) which enables an increase in the aspect ratio of the lower electrode. Because a lower electrode with a high aspect ratio is physically unstable, the associated semiconductor device makes use of a structure in which the distal end parts or the central part of the lower electrode are supported by beams (see for example Patent Documents 1 and 2).

### PATENT DOCUMENTS

Patent document 1: JP 2003-142605 A

Patent document 2: JP 2003-297952 A

### SUMMARY OF THE INVENTION

### Problems to be Solved by the Invention

A structure for coupling and supporting a plurality of crown-shaped lower electrodes with beams involves forming a capacitance insulating film not only on the surface of the lower electrode but also on the surface of the beam when forming the capacitance insulating film on the surface of the lower electrode. Whereas stress caused by the capacitance insulating film formed on the surface of the lower electrode is applied substantially uniformly over the entire lower electrode, stress caused by the capacitance insulating film formed on the surface of the beam acts locally in a direction perpendicular or almost perpendicular to the height direction of the lower electrode.

At the same time, an increase in the aspect ratio of a crown-shaped lower electrode brings about a reduction in the mechanical strength of the lower electrode. For example, the amount of deflection of the crown-shaped lower electrode is proportional to the cube of the height and inversely proportional to fourth power of the diameter. That is, the crown-shaped lower electrode tends to deform more easily as the height increases or as the lower electrode becomes narrower.

As a result, when the aspect ratio of the lower electrode increases, the stress caused by the capacitance insulating film formed on the surface of the beam coupling lower electrodes may lead to deformation (twisting) of the lower electrode. Deformation of the lower electrodes causes adjacent lower electrodes to come into contact with each other which leads to a short-circuit, thus causing a deterioration of the DRAM characteristics and leading to a reduction in yield.

### Solution to Problems

A semiconductor device manufacturing method according to a first embodiment of the present invention is characterized by: laminating a stopper film, a sacrificial film, and a beam constituent material film in succession on a semiconductor substrate; forming a cylinder hole that penetrates the stopper film, the sacrificial film, and the beam constituent material film; forming a lower electrode that covers the inner surface of the cylinder hole; patterning the beam constituent material film so as to form a beam that is connected to at least a portion of the external circumferential surface of the lower electrode, thereby exposing a portion of the sacrificial film; and removing the sacrificial film with wet etching and forming a hollow in the surface of the beam that is deeper than a hollow formed in the surface of the stopper film.

### Effects of Invention

By forming a hollow on the surface of the beam that is deeper than the hollow formed on the surface of the stopper film, the capacitor characteristics are not reduced due to the stopper film becoming a thin film, and the impact on the lower electrode caused by stress generated by the capacitance insulating film formed on the surface of the beam can be reduced.

### BRIEF DESCRIPTION OF THE DRAWINGS

FIG. 1 is a partial vertical cross-sectional view illustrating a configuration of a semiconductor device according to a first embodiment of the present invention.

FIG. 2(a) is an enlargement of the portion A in FIG. 1, and FIG. 2(b) is an enlarged cross-sectional view in the vicinity of the portion C in FIG. 1.

FIG. 3 is a cross-sectional view for explaining a method for manufacturing the semiconductor device in FIG. 1.

FIG. 4 is a cross-sectional view for explaining the step following the step illustrated in FIG. 3.

FIG. 5 is a cross-sectional view for explaining the step following the step illustrated in FIG. 4.

FIG. 6 is a cross-sectional view for explaining the step following the step illustrated in FIG. 5.

FIG. 7 is a plan view for illustrating a resist pattern used in the step following the step illustrated in FIG. 6.

FIG. 8 is a cross-sectional view for explaining the step following the step illustrated in FIG. 6.

FIG. 9 is a cross-sectional view for explaining the step following the step illustrated in FIG. 8.

FIG. 10 is a cross-sectional view for explaining the step following the step illustrated in FIG. 9.

FIG. 11 is a cross-sectional view for explaining the step following the step illustrated in FIG. 10.

FIG. 12 is a partial vertical cross-sectional view illustrating a configuration of a semiconductor device according to a second embodiment of the present invention.

FIG. 13(a) is an enlargement of the portion A in FIG. 12, and FIG. 13(b) is an enlarged cross-sectional view in the vicinity of the portion C in FIG. 12.

FIG. 14 is a cross-sectional view for explaining a method for manufacturing the semiconductor device in FIG. 12.

FIG. 15 is a plan view for illustrating a resist pattern used in the step following the step illustrated in FIG. 14.

FIG. 16 is a cross-sectional view for explaining the step following the step illustrated in FIG. 14.

FIG. 17 is a cross-sectional view for explaining the step following the step illustrated in FIG. 16.

FIG. 18 is a cross-sectional view for explaining the step following the step illustrated in FIG. 17.

FIG. 19 is a cross-sectional view for explaining the step following the step illustrated in FIG. 18.

FIG. 20 is a cross-sectional view for explaining the step following the step illustrated in FIG. 19.

FIG. 21 is a cross-sectional view for explaining the step following the step illustrated in FIG. 20.

FIG. 22 is a cross-sectional view for explaining the step following the step illustrated in FIG. 21.

FIG. 23 is a partial vertical cross-sectional view illustrating a configuration of a semiconductor device according to a third embodiment of the present invention.

FIG. 24 is a view illustrating the situation immediately after forming a lower electrode when manufacturing the semiconductor device in FIG. 23, and a view illustrating a portion corresponding to the portion A in FIG. 23.

FIG. 25 is an enlargement of the portion A in FIG. 23.

FIG. 26 is a cross-sectional view for explaining a method for manufacturing the semiconductor device in FIG. 23.

FIG. 27 is a cross-sectional view for explaining the step following the step illustrated in FIG. 26.

### EMBODIMENTS OF THE INVENTION

Embodiments of the present invention will be described in detail below with reference to the drawings.

### First Embodiment

(Configuration)

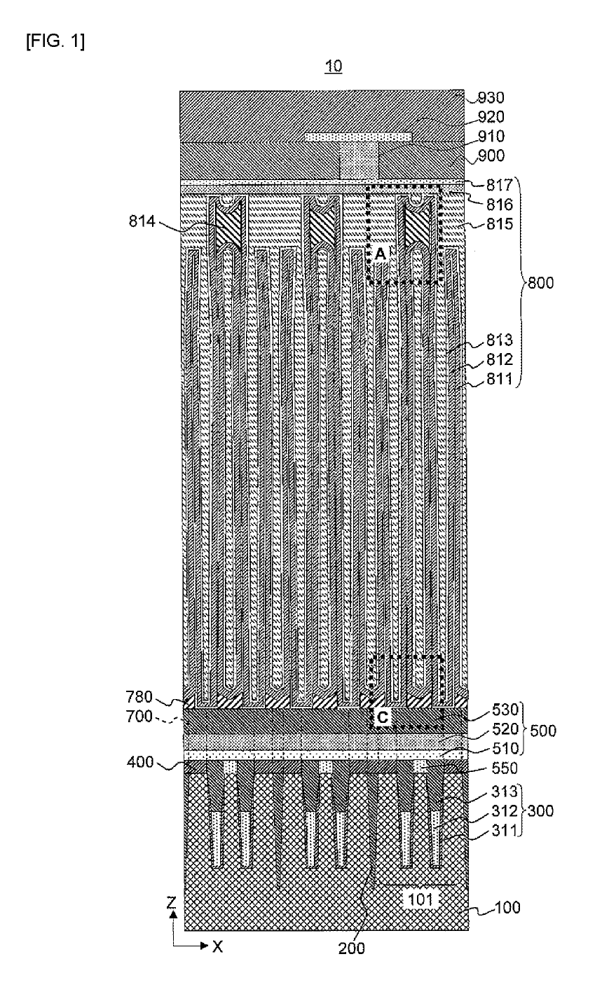

FIG. 1 is a partial vertical cross-sectional view of a semiconductor device 10 according to a first embodiment of the present invention. Specifically, FIG. 1 is a cross-sectional view of a portion of a DRAM memory cell area cut along a line that passes through the center of a bit line 500 disposed in the X direction (left-right direction in the diagram).

The semiconductor device 10 in FIG. 1 has a plurality of active regions 101 partitioned by the formation of element isolation regions 200 in a semiconductor substrate 100. The active regions 101 are disposed repeatedly in the X direction and also disposed repeatedly in the Y direction (front-back direction in diagram).

A pair of embedded word lines 300 are disposed in the Y direction so as to divide the active regions 101 into three regions in the X direction. The embedded word lines are formed so as to penetrate the plurality of active regions disposed repeatedly in the Y direction.

The respective embedded word lines 300 comprise a gate insulating film 311, a gate metal 312, and a cap insulating film 313. It should be noted that the upper part of the cap insulating film 313 protrudes from the upper surface of the active region 101 in FIG. 1, but the upper part of the cap insulating film 313 may also be flush with the upper surface of the active region 101.

A first interlayer insulating film 400 is disposed so as to cover the surface of the active regions 101 and the element isolation regions 200. While the upper surface of the first interlayer insulating film 400 and the upper surface of the cap insulating film 313 are flush in FIG. 1, the first interlayer insulating film 400 may be provided so as to bury the upper part of the cap insulating film 313.

A bit contact 550 connected to the upper surface of the active region 101 is provided between two embedded word lines 300 in the respective active regions 101. A bit line 500 is disposed so as to be connected to the bit contacts 550 formed in the plurality of active regions disposed repeatedly in the X direction.

The bit line 500 comprises a first conductive film 510, a second conductive film 520, and a cover film 530. The side surface in the Y direction of the bit line 500 has disposed thereon a liner film, which is not illustrated, that extends in the X direction.

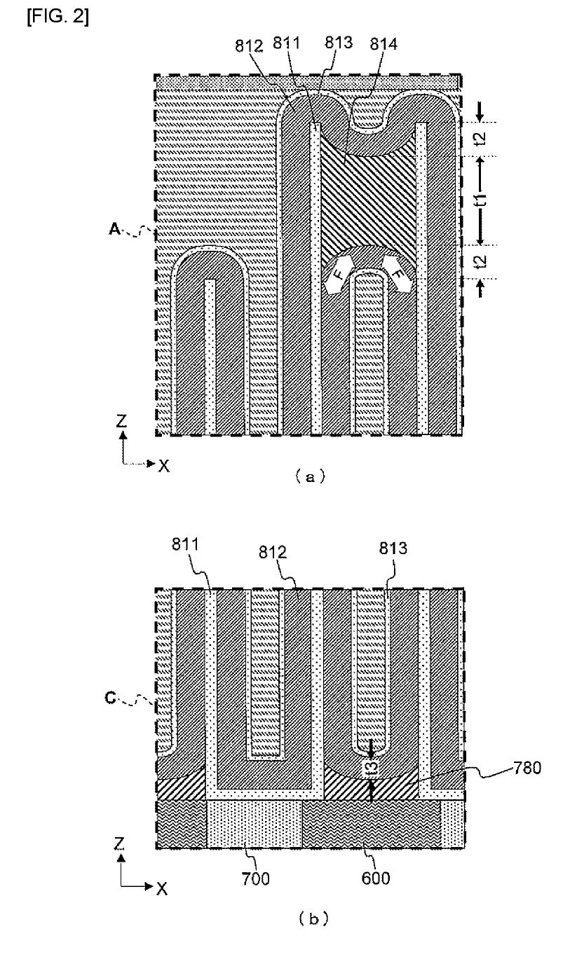

The plurality of bit lines 500 are disposed repeatedly in the Y direction in correspondence to the active regions 101 disposed repeatedly in the Y direction. Second interlayer insulating films (reference number 600 in FIG. 2(b)) are disposed between the bit lines 500 (between adjacent liner films).

A capacitive contact 700 is disposed so as to penetrate the second interlayer insulating film (600) and the first interlayer insulating film 400 and reach the upper surface of the active regions 101 in a region in which the bit lines 500 and the embedded word lines 300 do not overlap as seen in a plan view.

A stopper film 780 is disposed so as to cover the upper surface of the second interlayer insulating film (600).

A lower electrode 811 formed so as to penetrate the stopper film 780 is connected to the upper surface of each capacitive contact 700. The lower electrode 811 has a crown shape.

A capacitance insulating film 812 is formed so as to cover the surface of the lower electrode 811. An upper electrode 813 is formed so as to cover the surface of the capacitance insulating film 812.

A beam 814 is provided at the upper end part of the lower electrode 811 so as to couple adjacent lower electrodes 811.

A filling film 815 is formed so as to fill an area between adjacent upper electrodes 813. A capacitance plate 817 is formed on the filling film 815 with an adhesive film 816 interposed.

The lower electrode 811, the capacitance insulating film 812, the upper electrode 813, the filling film 815, the adhesive film 816, and the capacitance plate 817 form a plurality of crown-shaped capacitors 800 which are DRAM storage elements.

A third interlayer insulating film 900 is disposed on the capacitor 800. A wiring contact 910 connected to the capacitance plate 817 is disposed so as to penetrate the third interlayer insulating film 900.

Wiring 920 connected to the upper surface of the wiring contact 910 is disposed on the third interlayer insulating film 900, and a protective insulating film 930 is disposed so as to cover the wiring 920.

Next, a detailed explanation of the characteristic structure of the semiconductor device 10 is provided with reference to FIGS. 2(a) and 2(b). FIG. 2(a) is an enlargement of the portion A in FIG. 1 and FIG. 2(b) is an enlarged cross-sectional view in the vicinity of the portion C in FIG. 1. FIG. 2(b) depicts a cross-sectional plane at a position slightly shifted in the Y direction from the cross-sectional plane in FIG. 1, and depicts the capacitive contact 700.

As illustrated in FIG. 2(a), the beam 814 for coupling adjacent lower electrodes 811 is provided at the upper end part of the lower electrodes 811. As illustrated in FIG. 2(b), the stopper film 780 is provided near the bottom part of the lower electrodes 811.

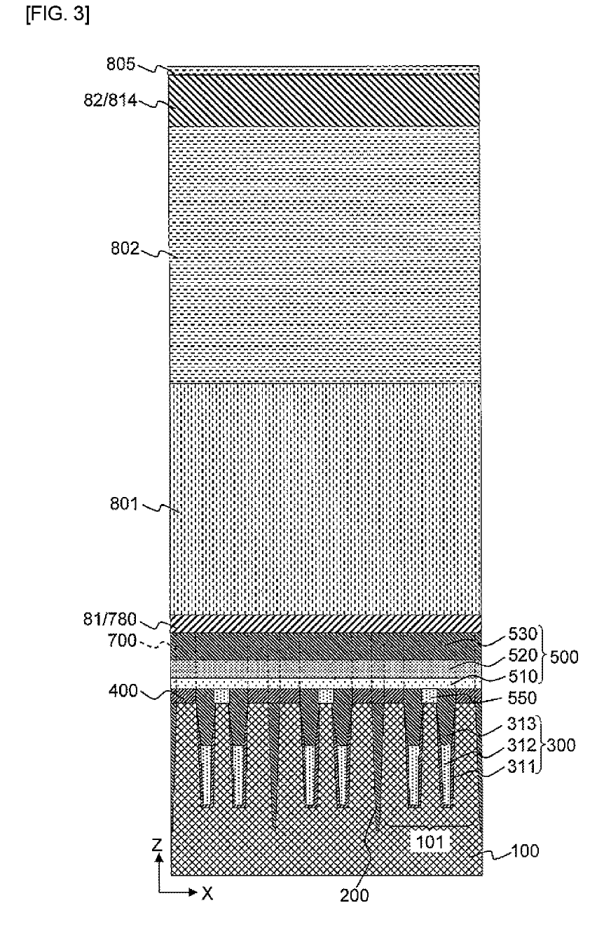

The beam 814 and the stopper film 780 are necessarily films that are difficult to etch using an etching liquid used to remove the sacrificial films (801, 802 in FIG. 3) used for forming the lower electrode 811. For example, the etching rate of the stopper film 780 is necessarily 1/10 or less of the etching rate of the sacrificial films. Silicon oxide films are normally used for the sacrificial films and silicon nitride films are normally used for the beam 814 and the stopper film 780.

Hollows are formed in the upper and lower surfaces of the beam 814 in the present embodiment, and the upper and lower surfaces have a curved shape. As a result, the orientation of internal stress F generated by the capacitance insulating film 812 formed on the upper and lower surfaces of the beam 814 is slanted away from the direction (XY in-plane direction) perpendicular to the height direction of the lower electrode 811 as illustrated in FIG. 2(a). That is, the orientation of the force acting on the lower electrode 811 from the capacitance insulating film 812 is set as far as possible to follow a direction (Z direction) parallel to the height direction of the lower electrode 812 to reduce the component in the direction perpendicular to the height direction of the lower electrode 811. As a result, deformation of the lower electrode 811 caused by stress from the capacitance insulating film 812 can be prevented or suppressed.

The hollow in the beam 814 is preferably deep. The reason for this is that the orientation of the stress of the capacitance insulating film 812 formed on the surface of the beam 814 approaches the height direction of the lower electrode 811. However, a deep hollow is also formed in the stopper film 780 made from the same element when there is an attempt to deepen the hollow in the beam 814. The stopper film 780 requires a uniform thickness in order to fulfill the purpose thereof. However, making the stopper film 780 thicker leads to a reduction in the capacity of the capacitor. Accordingly, there is a need to make the hollow in the beam 814 as deep as possible while keeping the hollow formed in the stopper film 780 as shallow as possible.

For example, film forming conditions are set such that the wet etching rate of the silicon nitride film that forms the beam 814 is 1.2 to 3 times the wet etching rate of the silicon nitride film that forms the stopper film 780. As a result, the depth of the hollow formed in the surface of the stopper film 780 can be limited to t3 (e.g., 2 to 4 nm) under etching conditions in which a hollow with a depth of t2 (e.g., 5 to 7 nm) is formed in the surface of the beam 814.

Because a reduction in the film thickness of the stopper film 780 can be suppressed, the possibility of the chemical solution (etching liquid) penetrating the stopper film 780 and eroding the second interlayer insulating film 600 around the capacitive contact 700 can be reduced. Moreover, the processing time can be reduced because there is no need to increase the etching time in order to form the relatively deep hollow in the beam 814.

(Manufacturing Method)

A method for manufacturing the semiconductor device 10 will be described next with reference to FIGS. 3 to 11.

In the following description, a silicon nitride film having a relatively slow etching rate is referred to as a SiN film A, and a silicon nitride film having a relatively fast etching rate is referred to as a SiN film B. The SiN film A etching rate is no more than 1/10 the etching rate of an oxide film subject to etching. The SiN film B etching rate is approximately 1.2 to 3 times that of the SiN film A.

Steps up to the formation of the second sacrificial oxide film 802 depicted in FIG. 3 are first of all performed using well-known methods.

Specifically, the element isolation region 200 is formed first on the semiconductor substrate 100. As a result, the surface side of the semiconductor substrate 100 is divided into a plurality of active regions 101.

Next, the embedded word lines 300 made up of the gate insulating film 311, the gate metal 312, and the cap insulating film 313 are formed.

The entire surface of the semiconductor substrate 100 is then covered by the first interlayer insulating film 400.

The bit contacts 550 connected to the active regions 101 are formed next so as to penetrate the first interlayer insulating film 400. The bit line 500 made up of the first conductive film 510, the second conductive film 520, and the cover film 530 is formed so as to be connected to the bit contacts 550. The liner film (not illustrated) is formed so as to cover the side surface of the bit line 500.

The entire surface of the semiconductor substrate 100 is next covered with the second interlayer insulating film (600 in FIG. 2(b). The capacitive contacts 700 (indicated with dashed lines because it is not visible in FIG. 3) connected to the active regions 101 are then formed at positions not overlapping either of the embedded word lines 300 or the bit line 500.

Next, a SiN film A 81, the first sacrificial oxide film 801, and the second sacrificial oxide film 802 that make up the stopper film 780 are formed in succession. A borophosphosilicate glass (BPSG) film may be used as the first sacrificial oxide film 801, and a plasma tetraethyl orthosilicate (TEOS) film may be used as the second sacrificial oxide film 802. If the height of the capacitor 800 is set to 1.15 μm for example, the respective thicknesses of the SiN film A 81, the first sacrificial oxide film 801, and the second sacrificial oxide film 802 may be 30 nm, 550 nm, and 500 nm.

Film formation conditions are set such that the etching rate of the SiN film A 81 employing the etching liquid used for wet etching the first sacrificial oxide film 801 and the second sacrificial oxide film 802 is no more than 1/10 of the etching rate of the first sacrificial oxide film 801 and the second sacrificial oxide film 802. When the SiN film A 81 is formed by a plasma CVD method that uses trimethyldisilane, SiH₄, and NH₃ as source gases, the etching rate can be varied by varying the flow rate of the trimethyldisilane.

Next, a SiN film B 82 is formed to a thickness of about 200 nm for example as the beam constituent material film that will subsequently become the beam 814 on the second sacrificial oxide film 802. The thickness of the SiN film B 82 is set to a thickness that allows for the required thickness (t1 in FIG. 2(a) for the beam 814 to remain after the oxide film wet etching.

The SiN film B 82 can be formed by using, for example, a plasma CVD device under the conditions of a temperature of 500 to 550° C., a chamber pressure of 3 to 5 Pa, and a source gas of 0 to 50 sccm of trimethyldisilane, 100 to 300 sccm of SiH₄, and 400 to 600 sccm of NH₃. The formation of the SiN film A 81 should be performed under conditions in which the flow rate of the trimethyldisilane is higher than in the above conditions. In other words, the formation of the SiN film B 82 is performed with a lower trimethyldisilane flow rate (the flow rates of SiH₄ and NH₃ are the same) in comparison with the film formation conditions for the SiN film A 81.

By forming the SiN film B 82 under the above conditions, the etching rate produced by the etching liquid used for wet etching the first sacrificial oxide film 801 and the second sacrificial oxide film 802 can be 1.2 to 3 times the etching rate of the SiN film A 81.

A fifth sacrificial oxide film 805 is formed next on the SiN film B 82. A plasma TEOS film may be used as the fifth sacrificial oxide film 805.

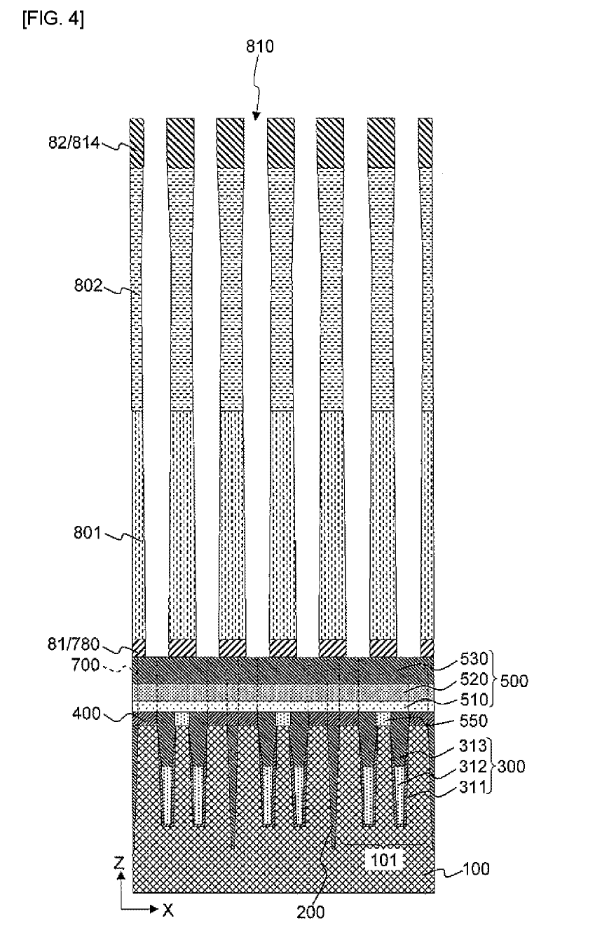

As illustrated in FIG. 4, a lithography technique and a dry etching technique are then used to open cylinder holes 810 that penetrate the SiN film B 82, the second sacrificial oxide film 802, the first sacrificial oxide film 801, and the SiN film A 81.

The cylinder holes 810 readily assume a bowing shape because the cylinder holes 810 are deep holes with a high aspect ratio that exceed a depth of 1 μm while the diameter of the cylinder is approximately 55 nm for example. Accordingly, the fifth sacrificial oxide film 805 is formed beforehand on the SiN film B 82 and then the fifth sacrificial oxide film 805 is etched back and removed after the formation of the cylinder holes 810. As a result, the opening of the cylinder holes 810 is increased by removing the narrow opening portions formed in the fifth sacrificial oxide film 805 and exposing the opening parts of the SiN film B 82 having a larger diameter.

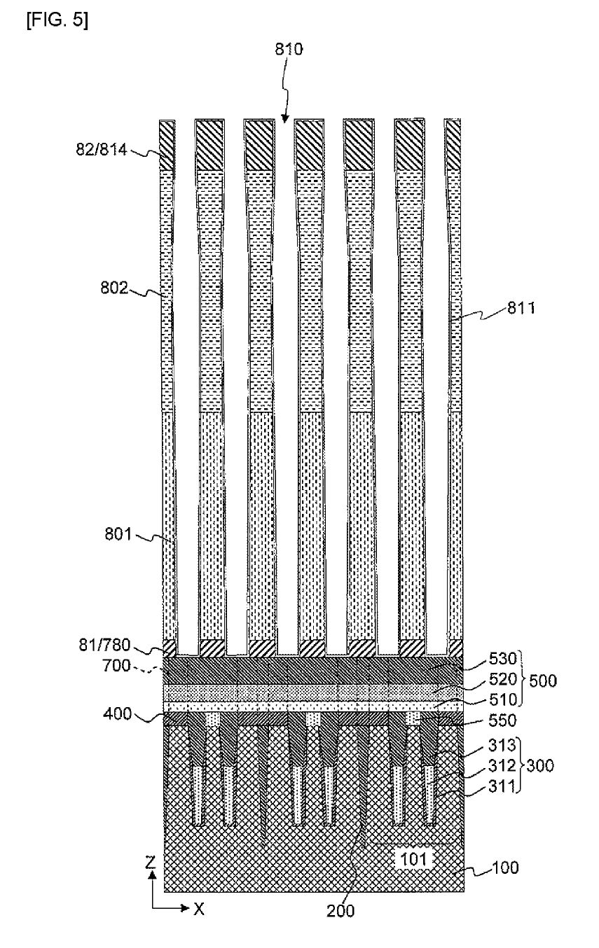

As illustrated in FIG. 5, a TiN film, which will become the lower electrode 811 of the capacitor, is formed next with a film thickness of approximately 13 nm.

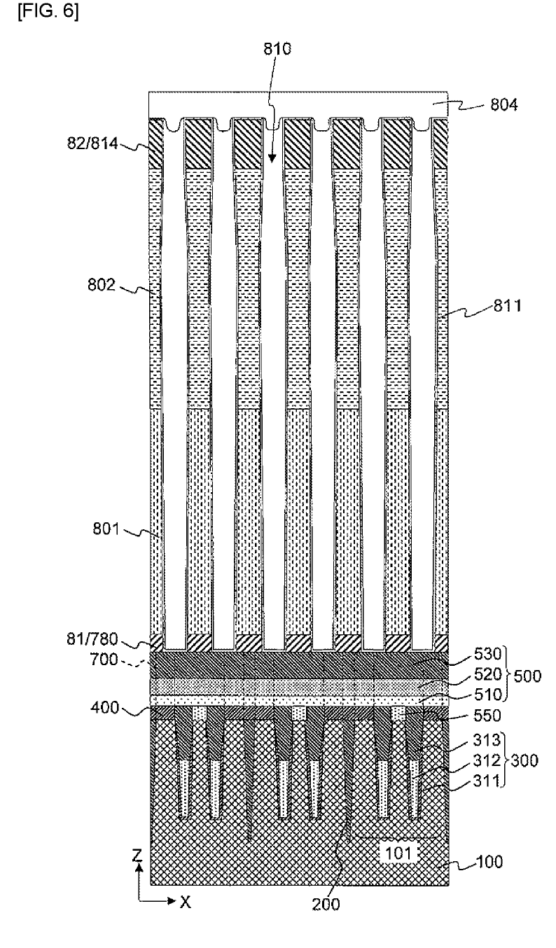

As illustrated in FIG. 6, an 80-nm plasma TEOS film is formed next as a fourth sacrificial oxide film 804. The plasma TEOS film is formed so as to act as a lid on the cylinder holes 810 because the coverage properties are poor.

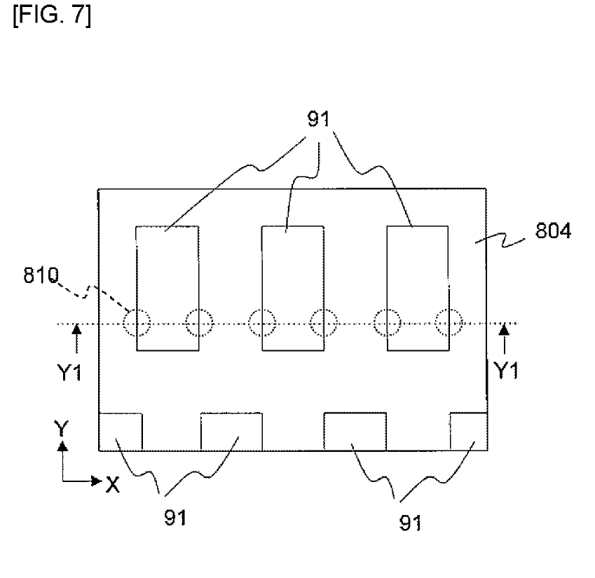

A resist mask 91 having a pattern as illustrated in FIG. 7 is formed next on the fourth sacrificial oxide film 804. In order to understand the positional relationship with the resist mask 91, some (six) of the plurality of cylinder holes 810 formed in an array are indicated with dashed lines in FIG. 7. As can be seen in FIG. 7, the resist mask 91 is formed so as to cover portions of the cylinder holes 810. The line Y1-Y1 corresponds to the cross-section position in FIG. 6.

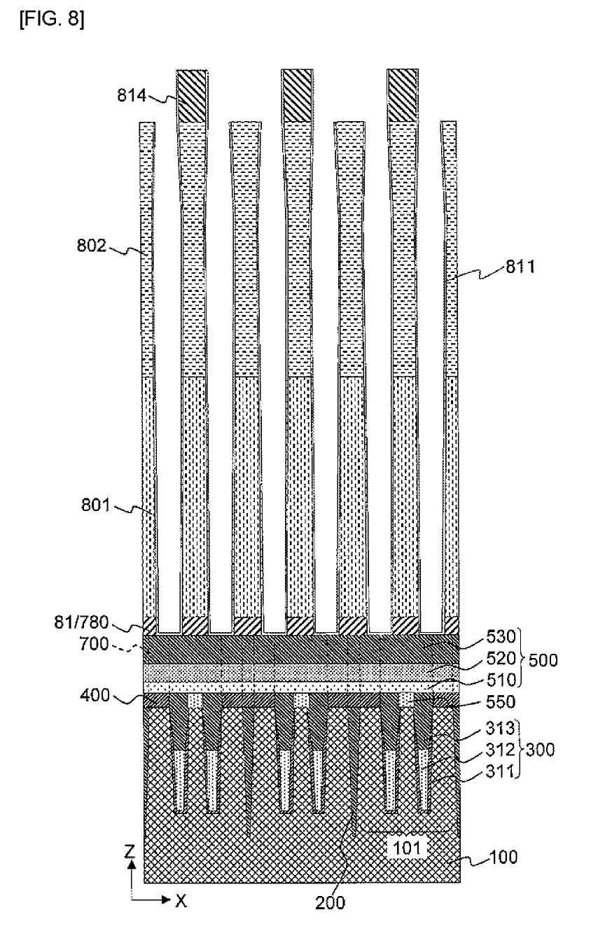

The fourth sacrificial oxide film 804, the lower electrode 811, and the SiN film B 82 are then subjected to dry etching using the resist mask 91. After the resist mask 91 is removed, the fourth sacrificial oxide film 804 is then etched back and the lower electrode 811 present on the SiN film B 82 is removed. In this way, a structure can be arrived at in which the respective lower electrodes 811 of the capacitor 800 are separated and adjacent lower electrodes 811 are coupled by the beams 814 as illustrated in FIG. 8. That is, the beams 814 are connected to at least a portion of the external circumferential surface of each lower electrode 811. The stopper films 780 are connected to the external circumferential surface of the lower end part of the lower electrodes 811.

The shape pattern of the beams 814 is not limited to the pattern illustrated in FIG. 7. The beams 814 should be formed so as to couple two or more adjacent lower electrodes 811.

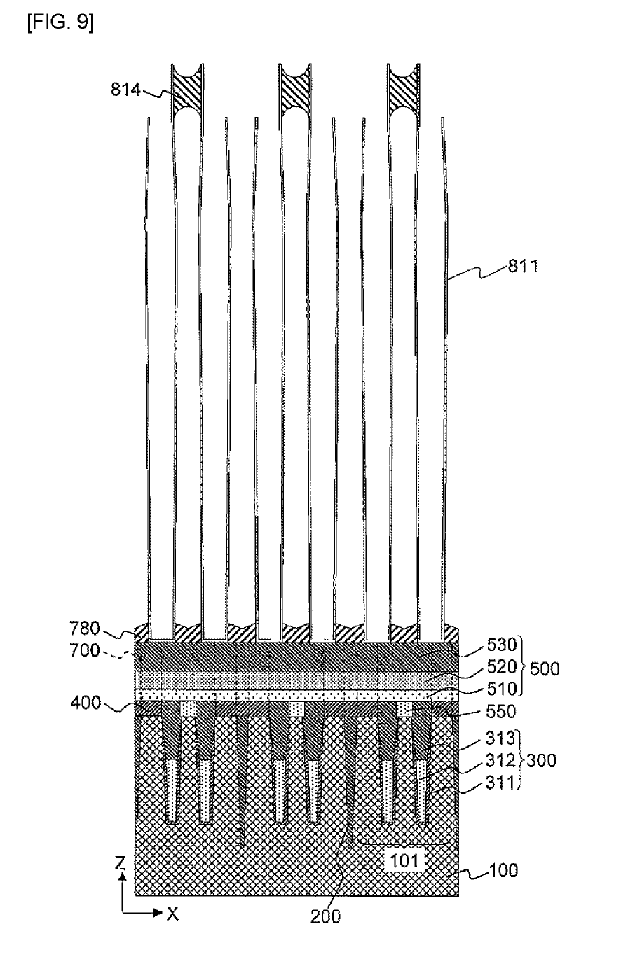

As illustrated in FIG. 9, the first sacrificial oxide film 801 and the second sacrificial oxide film 802 are then removed using wet etching. Hydrofluoric acid with a concentration of 50%, for example, may be used as the etching liquid for the oxide film wet etching. At this time, the surface of the stopper film 780 (SiN film A 81) is etched slightly to form a relatively shallow hollow. The beams 814 are formed with relatively deep hollows on the upper and lower surfaces due to the SiN film B 82 being adapted to have an etching rate 1.2 to 3 times that of the SiN film A 81. The relatively deep hollows formed in the beams 814 reduce the impact of stress from the subsequently formed capacitance insulating film 812 acting on the lower electrodes 811. Conversely, the stopper film 780 is subject to a smaller amount of etching and thus is able to obstruct the penetration of the chemical solution without the film thickness increasing during formation. As a result, erosion of the second interlayer insulating film 600 present around the capacitive contact 700 can be prevented. Moreover, no reduction occurs in the capacity of the capacitor 800.

The lower electrodes 811 of the capacitor 800 in which the beams 814 are disposed in the upper end parts of the crown-shaped capacitor are manufactured as described above.

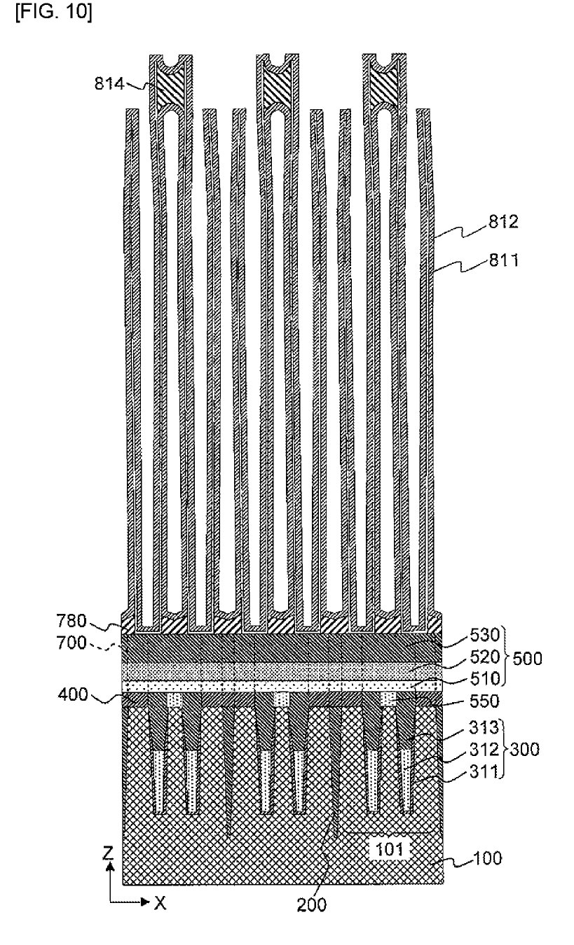

As illustrated in FIG. 10, the capacitance insulating film 812 is then formed on the surface of the lower electrodes 811, the surface of the stopper film 780, and the surfaces (upper and lower surfaces) of the beams 814 using a known method. Because the hollows are formed on the surfaces of the beams 814 so that the cross-sectional shape thereof is curved, the direction of the stress from the capacitance insulating film 812 is slanted with respect to a direction (XY in-plane direction) perpendicular to the height direction of the lower electrodes 811 (see FIG. 2(a)), and thus warping of the lower electrodes 811 is less likely to occur.

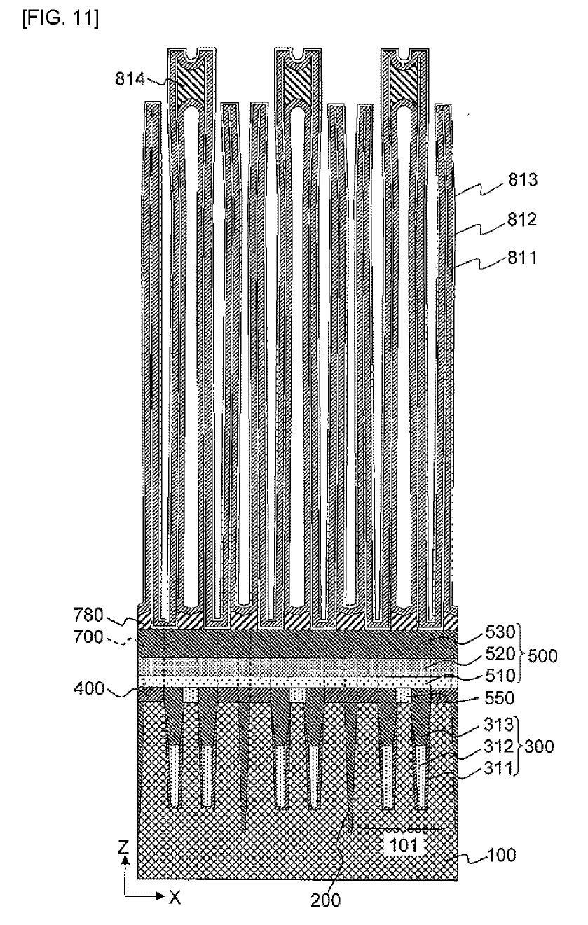

As illustrated in FIG. 11, the upper electrodes 813 are then formed on the surface of the capacitance insulating film 812 using a known method.

Next, the filling film 815, the adhesive film 816, the capacitance plate 817, the third interlayer insulating film 900, the wiring contact 910, the wiring 920, and the protective insulating film 930 are formed in succession using a known method to complete the semiconductor device 10 illustrated in FIG. 1.

As described above, the etching amount of the stopper film can be restricted and relatively deep hollows can be formed in the upper and lower surfaces of the beams in the semiconductor device having a structure in which the beams are disposed in the upper end part of the crown-shaped capacitor according to the present embodiment. As a result, the film thickness of the stopper film is not increased, etching of the third interlayer insulating film around the capacitive contact can be prevented, and deformation of the lower electrodes due to stress from the capacitance insulating film can be prevented.

### Second Embodiment

(Configuration)

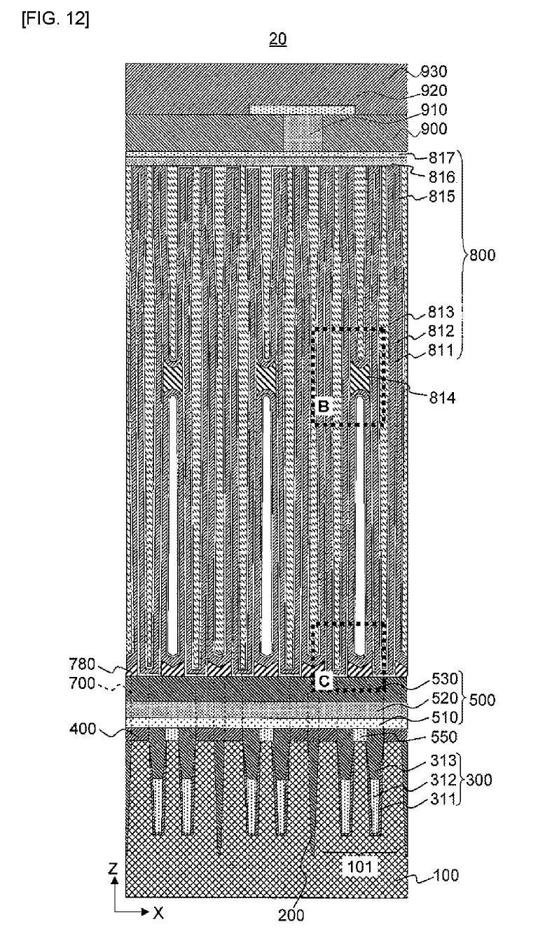

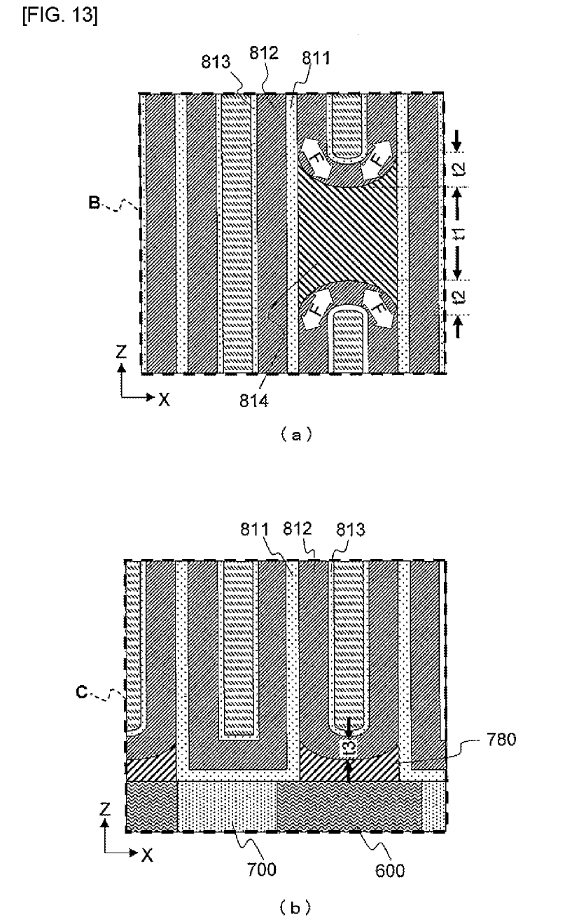

The following is a description of a second embodiment of the present invention, given with reference to FIGS. 12, 13(a), and 13(b).

FIG. 12 is a partial vertical cross-sectional view illustrating a semiconductor device 20 according to a second embodiment of the present invention. Elements that are the same as those of the semiconductor device 10 according to the first embodiment are provided with the same reference numerals and descriptions thereof are omitted.

The beams 814 are disposed in the upper end part of the crown-shaped capacitor 800 in the first embodiment, but the beams 814 are disposed in an intermediate part (positions remote from the upper end part and the lower end part) in the height direction of the crown-shaped capacitor in the present embodiment.

Next, a detailed description of the characteristic structure of the semiconductor device 20 is provided with reference to FIGS. 13(a) and 13(b).

FIG. 13(a) is an enlargement of the portion B in FIG. 12, and FIG. 13(b) is an enlarged cross-sectional view in the vicinity of the portion C in FIG. 12.

The upper and lower surfaces of the beams 814 are formed with relatively deep (depth t2) hollows in the present embodiment. Conversely, relatively shallow hollows (depth t3<t2) are formed in the upper surface of the stopper film 780. The film formation conditions of the films are adjusted such that the etching rate of the SiN film B 82 that forms the beams 814 is 1.2 to 3 times the etching rate of the SiN film A 81 that configures the stopper film 780. As a result, the depth t3 of the hollows of the stopper film 780 can be set to 2 to 4 nm when the depth t2 of the hollows of the beams 814 is, for example, 5 to 7 nm.

By forming the relatively deep hollows in the surfaces of the beams 814, the direction of the stress F applied to the lower electrodes 811 from the capacitance insulating film 812 formed on the surfaces of the beams 814 can be slanted away from the direction (XY in-plane direction) perpendicular to the height direction of the lower electrodes 811. As a result, deformation of the lower electrodes 811 can be prevented or suppressed.

Conversely, penetration of the chemical solution and the possibility of erosion of the second interlayer insulating film 600 around the capacitive contact 700 can be reduced because the hollows in the stopper film 780 are kept shallow.

Moreover, because there is no need to increase the etching processing time in order to form the relatively deep hollows in the surfaces of the beams 814, the processing time can be reduced.

(Manufacturing Method)

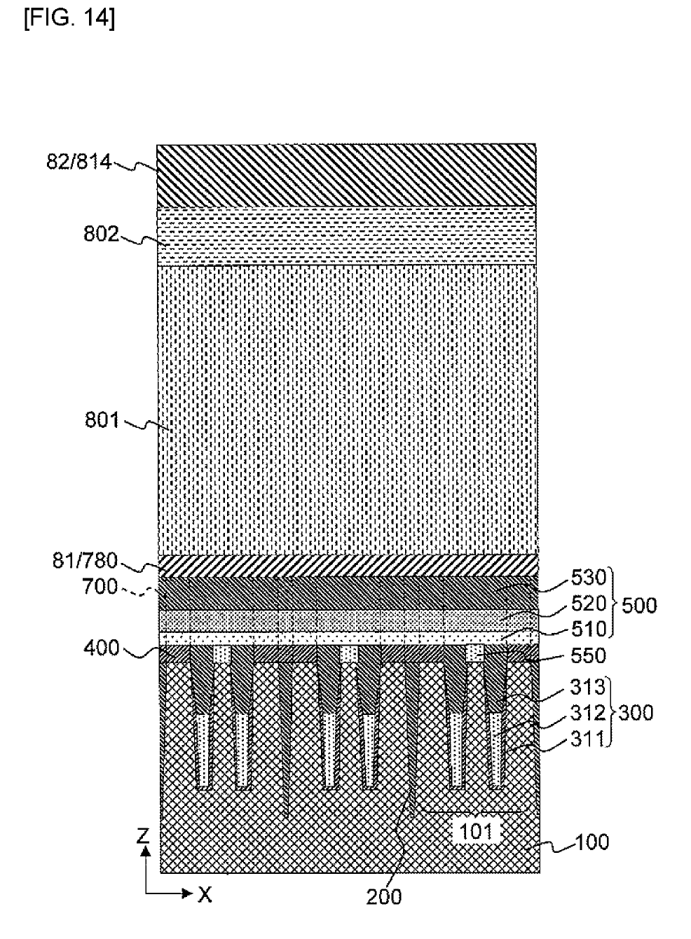

A method for manufacturing the semiconductor device 20 will be described next with reference to FIGS. 14 to 21.

As illustrated in FIG. 14, the steps up to the formation of the SiN film B 82 that becomes the beams 814 are first of all performed using the same method as in the first embodiment.

The respective film thicknesses of the stopper film 780, the first sacrificial oxide film 801, the second sacrificial oxide film 802, and the SiN film B 82 may be set to 30 nm, 550 nm, 200 nm, and 200 nm for example. The above film thicknesses are based on the assumption that the beams 814 are formed at positions about 850 nm from the bottom, with the height of the capacitor 800 formed thereafter being 1.15 μm.

The SiN film B 82 in the present embodiment is formed in such a way that the etching rate thereof is 1.2 to 3 times the etching rate of the SiN film A 81. The formation of the SiN film B 82 can be achieved by using, for example, a plasma CVD device under the conditions of a temperature of 500 to 550° C., a chamber pressure of 3 to 5 Pa, and a source gas of 0 to 50 sccm of trimethyldisilane, 100 to 300 sccm of SiH₄, and 400 to 600 sccm of NH₃ in the same way as in the first embodiment. The flow rate of the trimethyldisilane should be increased in comparison to the above conditions when forming the stopper film 780 (SiN film A 81).

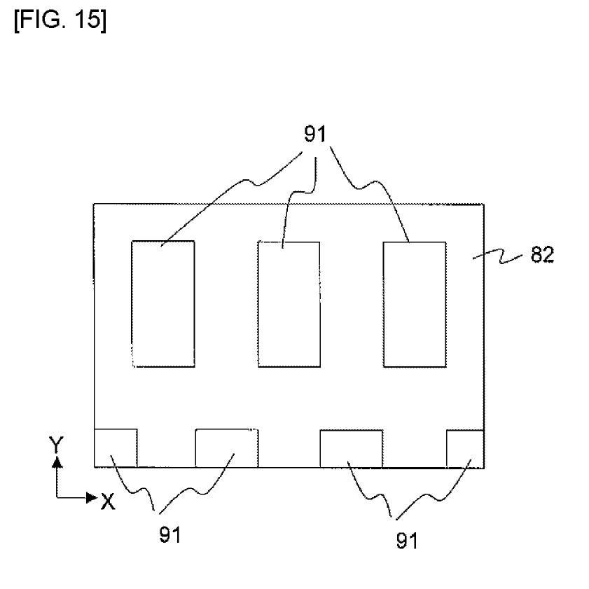

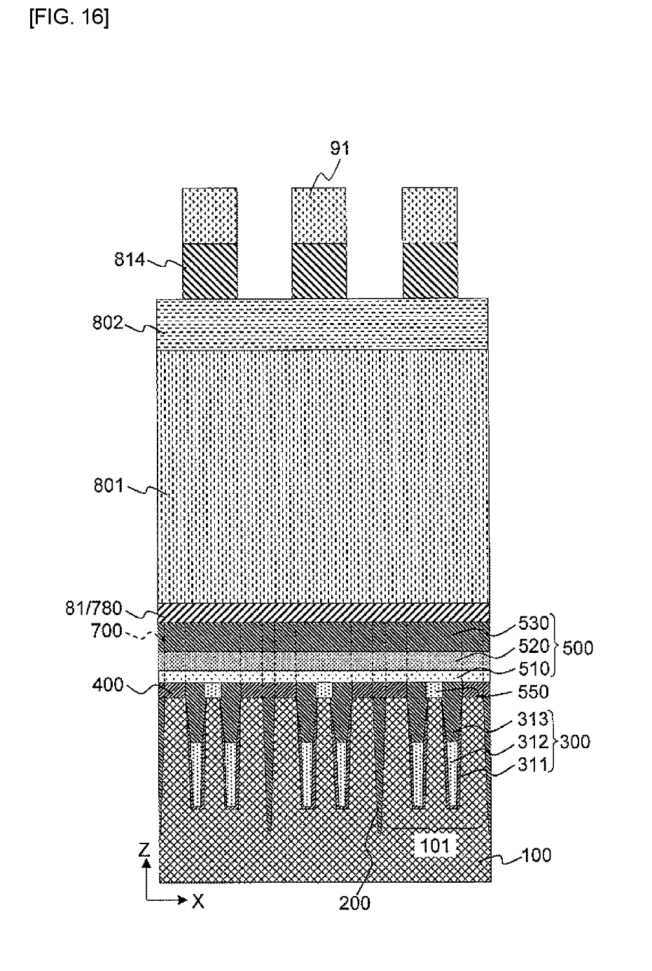

Next, the resist mask 91 having the pattern depicted in FIG. 15 is formed on the SiN film B 82. The SiN film B 82 is etched as illustrated in FIG. 16 by dry etching using the resist mask 91 to form the beams 814. The pattern of the beams 814 is not limited to the pattern illustrated in FIG. 15.

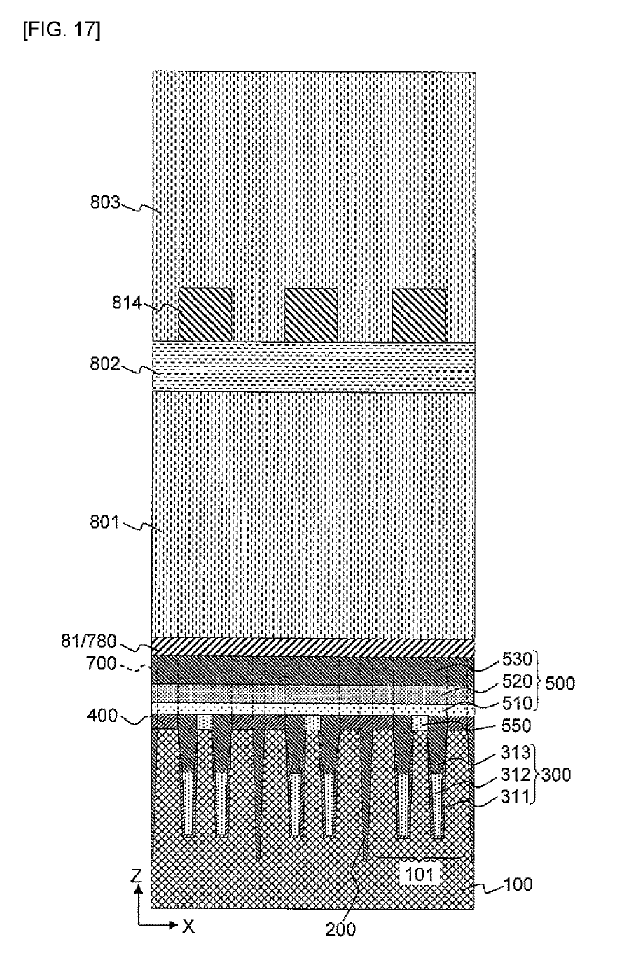

As illustrated in FIG. 17, a third sacrificial oxide film 803 is formed next so as to embed the beams 814. The height of the capacitor 800 is determined by the thickness of the third sacrificial oxide film 803. The thickness of the third sacrificial oxide film 803 is approximately 330 nm when the height of the capacitor 800 is set to 1.15 μm.

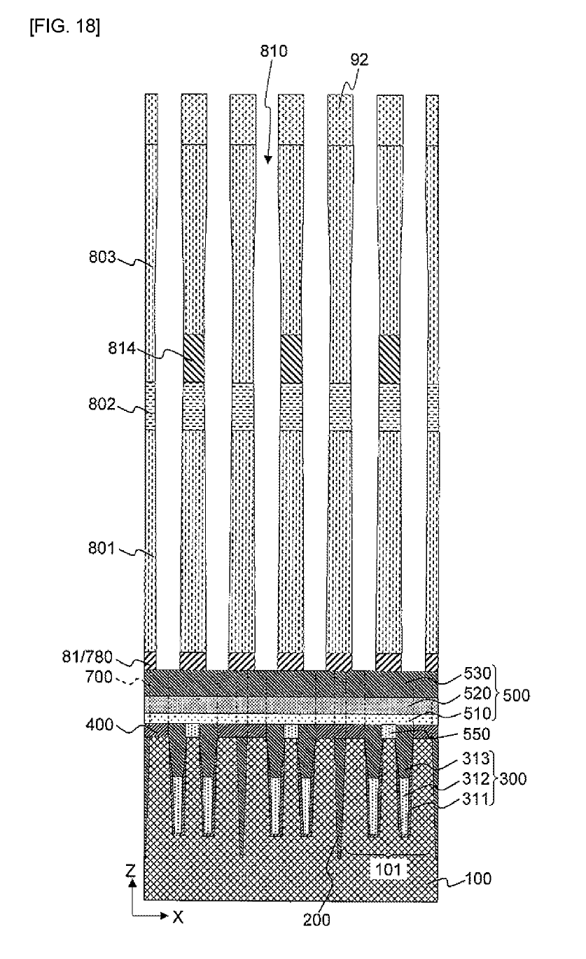

As illustrated in FIG. 18, a resist mask 92 is then formed on the third sacrificial oxide film 803, and the cylinder holes 810 are opened using a lithography technique and a dry etching technique.

The cylinder holes 810 readily assume a bowing shape because the cylinder holes 810 are deep holes with a high aspect ratio that exceed a height of 1 μm while the diameter of the cylinder is approximately 55 nm for example. Accordingly, after the resist mask 92 is removed, the third sacrificial oxide film 803 may be etched back as needed so as to remove a portion thereof. As a result, the opening can be increased and the bowing shape can be improved.

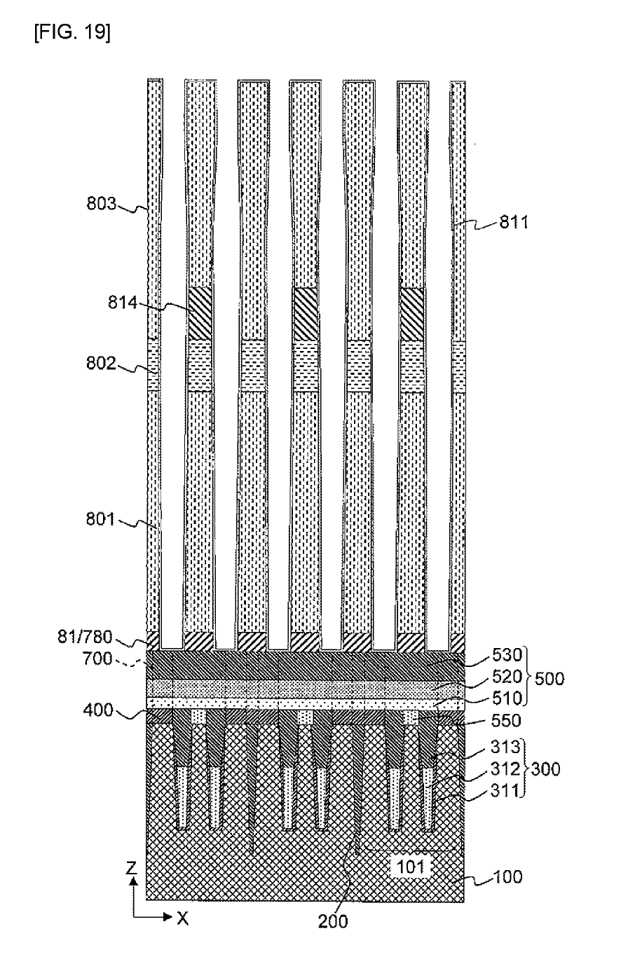

As illustrated in FIG. 19, the TiN film, which will become the lower electrode 811 of the capacitor, is formed next with a film thickness of approximately 13 nm for example. The formed TiN film is then etched back with dry etching and the TiN film present on the upper surface of the third sacrificial oxide film 803 is removed. As a result, the plurality of lower electrodes 811 corresponding to the cylinder holes 810 are separated.

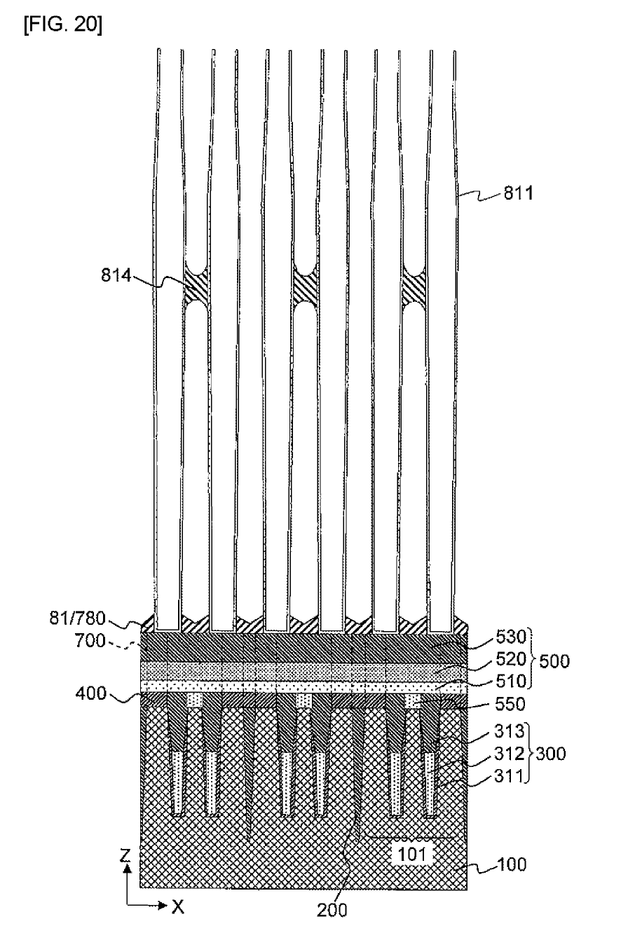

As illustrated in FIG. 20, oxide film wet etching is performed next and the first sacrificial oxide film 801, the second sacrificial oxide film 802, and the third sacrificial oxide film 803 above the stopper film 780 are removed. Hydrofluoric acid with a concentration of 50% may be used for this etching. In this way the lower electrodes 811 of the crown-shaped capacitor 800 in which the beams 814 are disposed in the intermediate part can be manufactured.

The upper surface of the stopper film 780 and the upper and lower surfaces of the beams 814 are etched when the first to third sacrificial oxide films 801 to 803 are removed. As described above, the beams 814 comprise the SiN film B 82 having an etching rate 1.2 to 3 times faster than that of the SiN film A 81 that forms the stopper film 780. As a result, the relatively deep hollows (curved shape portions) can be formed on the surfaces of the beams 814 while keeping the erosion of the stopper film 780 to a low level.

Moreover, the penetration of chemical solutions can be prevented without increasing the film thickness of the stopper film 780 and erosion of the second interlayer insulating film 600 around the capacitive contact 700 can be prevented because the hollows formed in the stopper film 780 are relatively shallow. The problem of the reduction in capacity of the capacitor 800 does not occur because there is no need to increase the film thickness of the stopper film 780.

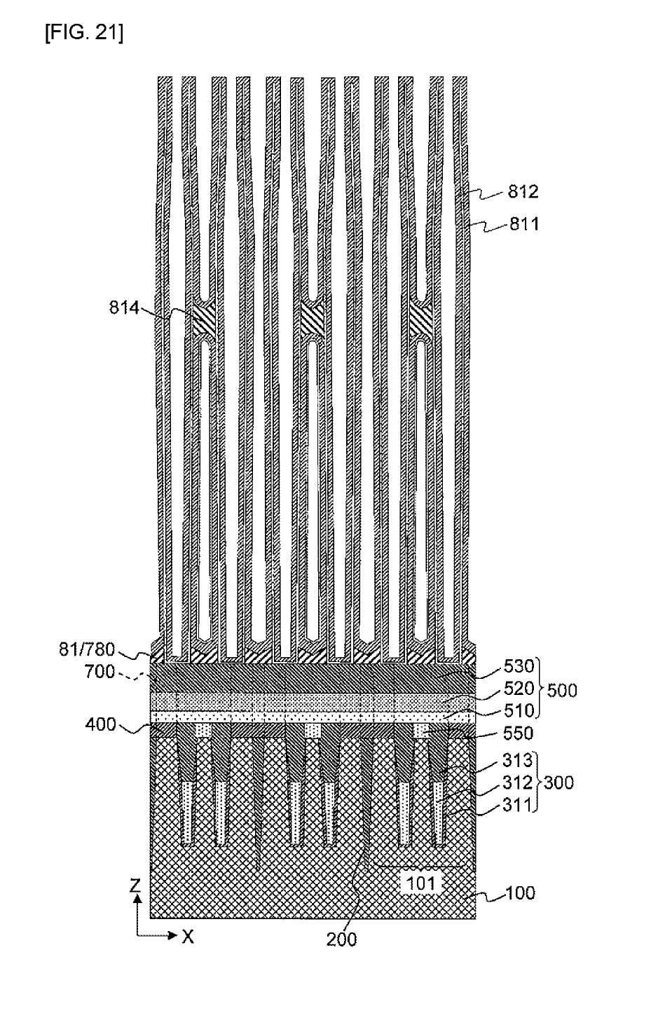

As illustrated in FIG. 21, the capacitance insulating film 812 is then formed on the surface of the lower electrodes 811 and the surface of the stopper film 780 using a known method. Because the surfaces of the beams 814 are curved, the direction of the stress from the capacitance insulating film 812 is slanted with respect to the direction (XY in-plane direction) perpendicular to the height direction of the lower electrodes 811, and warping of the lower electrodes 811 is less likely to occur.

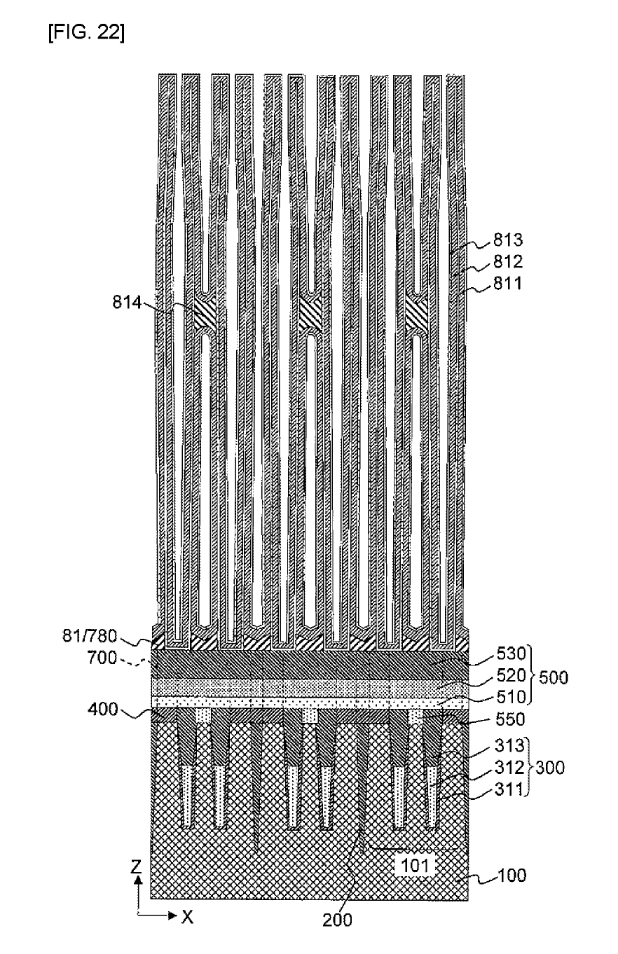

As illustrated in FIG. 22, the upper electrodes 813 are then formed on the surface of the capacitance insulating film 812 using a known method.

Next, the filling film 815, the adhesive film 816, the capacitance plate 817, the third interlayer insulating film 900, the wiring contact 910, the wiring 920, and the protective insulating film 930 are formed in succession using a known method to complete the semiconductor device 20 illustrated in FIG. 12.

According to the present embodiment, the same effects as in the first embodiment can also be achieved in a semiconductor device having a structure in which the beams are disposed in the intermediate part of the crown-shaped capacitor.

### Third Embodiment

(Configuration)

The beams 814 in the first and second embodiments are formed by a single SiN film B 82. The SiN film B 82 has a faster etching rate than the SiN film A 81 that forms the stopper film 780 and it is difficult to control the film thickness after the oxide film wet etching to the required thickness t1 for the beams. Moreover, the SiN film B 82 is mechanically weaker than the SiN film A 81.

Accordingly, a film with a three-layer structure (sandwich structure) is used as the film for forming the beams 814 in a third embodiment of the present invention. Specifically, the SiN film A 81 is disposed in the middle and the SiN films B 82 are disposed on the upper and lower sides of the SiN film A 81.

The three-layer structure beams 814 may be disposed in the upper end parts of the lower electrodes 811 as in the first embodiment, or may be disposed in the intermediate parts of the lower electrodes 811 as in the second embodiment.

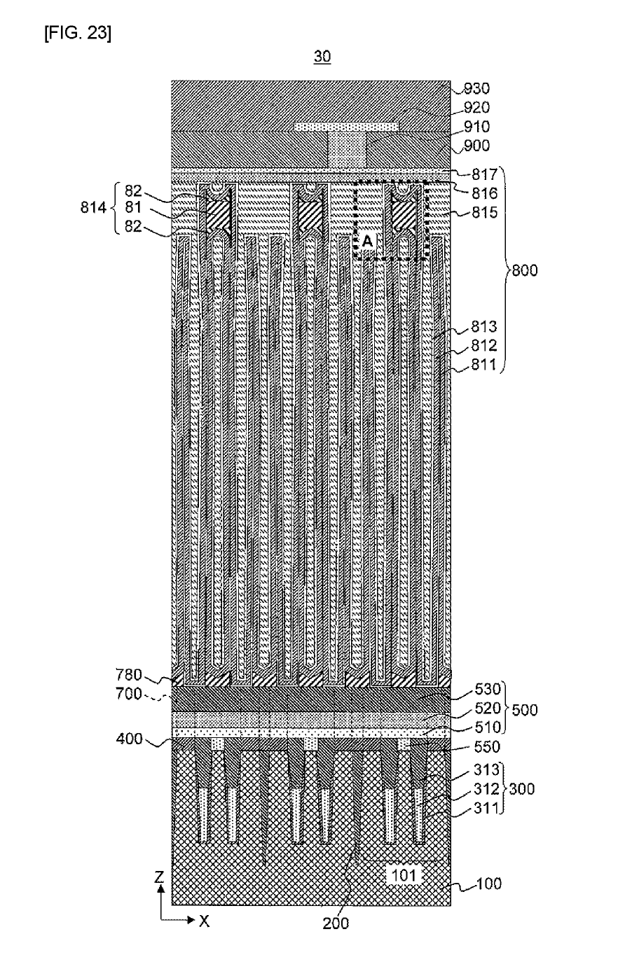

FIG. 23 is a partial cross-sectional view of a semiconductor device 30 in which beams 814 having a three-layer structure are disposed in the upper end parts of the lower electrodes 811 according to the present embodiment. The configuration of the semiconductor device 30 is the same as that of the first embodiment except for the structure of the beams 814.

The beams 814 are formed in a sandwich structure in which the SiN film A 81 is sandwiched from above and below by the SiN films B 82.

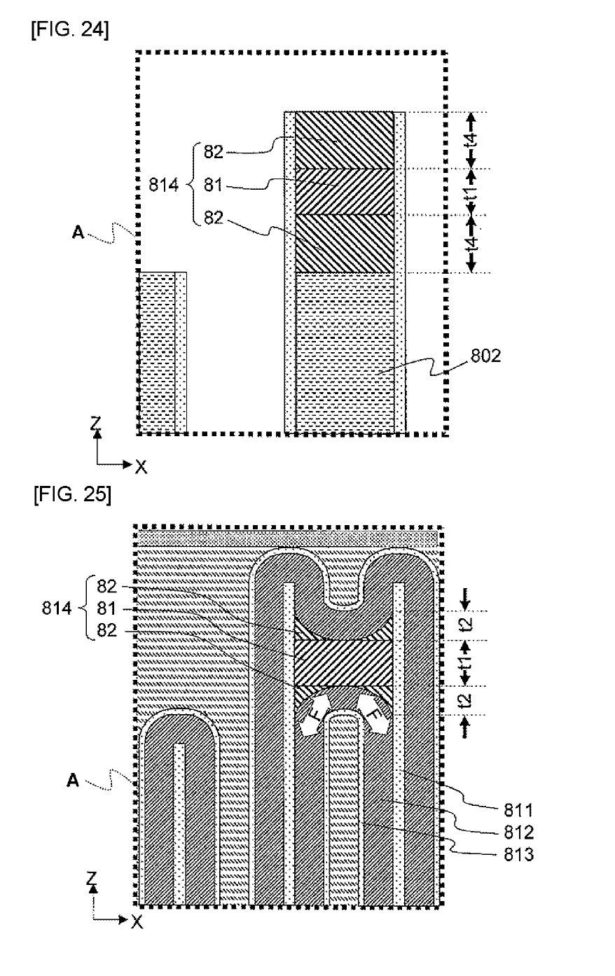

A detailed description of the beams 814 in the semiconductor device 30 will be given next with reference to FIGS. 24 and 25.

FIG. 24 is an enlargement of a portion corresponding to the portion A in FIG. 23 in a state immediately after the lower electrodes 811 have been formed (corresponding to FIG. 8). FIG. 25 is an enlargement of the portion A in FIG. 23.

As illustrated in FIG. 24, before performing the oxide film wet etching step to remove the second sacrificial oxide film 802 and the like, a lower layer side SiN film B 82 is formed with a thickness t4 (e.g., 60 nm) on the second sacrificial oxide film 802. The SiN film A 81 is formed with a thickness t1 (e.g., 80 nm) as required for the beams 814 on the lower layer side SiN film B 82. Further, an upper layer side SiN film B 82 is formed with a thickness t4 (e.g., 60 nm) on the SiN film A 81.

When oxide film wet etching is performed to remove the first and second sacrificial oxide films (801, 802) in the state in which the beams 814 having the three-layer structure are formed in this way, the surfaces of the upper layer side and the lower layer side SiN films B 82 are etched so that hollows having a depth t2 (e.g., 5 to 7 nm) are formed as illustrated in FIG. 25. Even when the SiN film B 82 is etched and the SiN film A 81 is exposed, the etching rate of the SiN film A 81 is slower than the etching rate of the SiN film B 82. Moreover, the SiN film A 81 becomes exposed as the completion time of the etching processing approaches. As a result, the SiN film A 81 is essentially not etched and mostly maintains the film thickness of t1. Consequently, the thickness t1 required for the beams 814 can be maintained and the required strength can be ensured.

(Manufacturing Method)

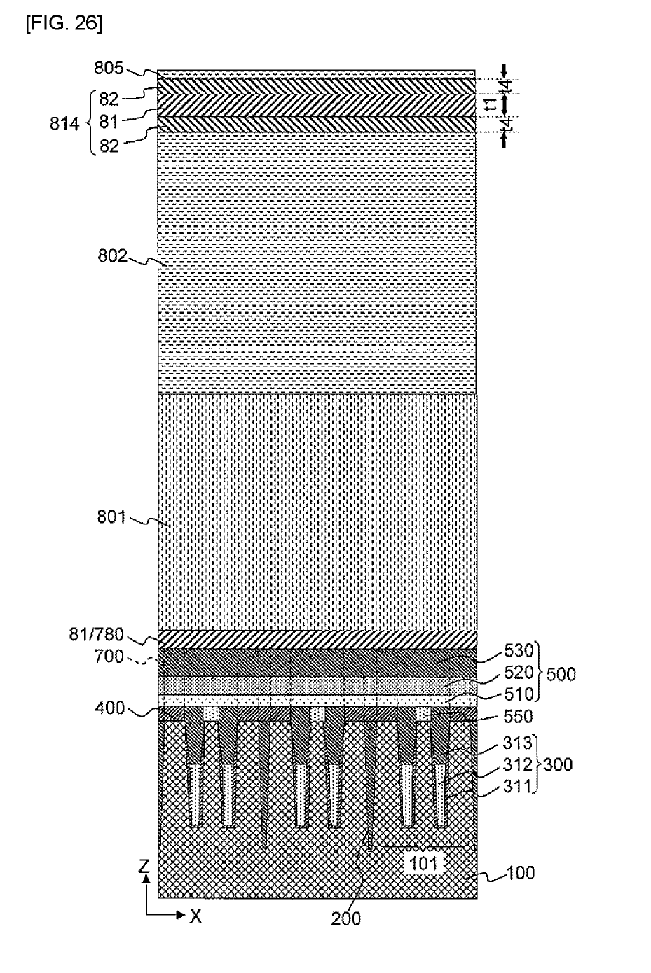

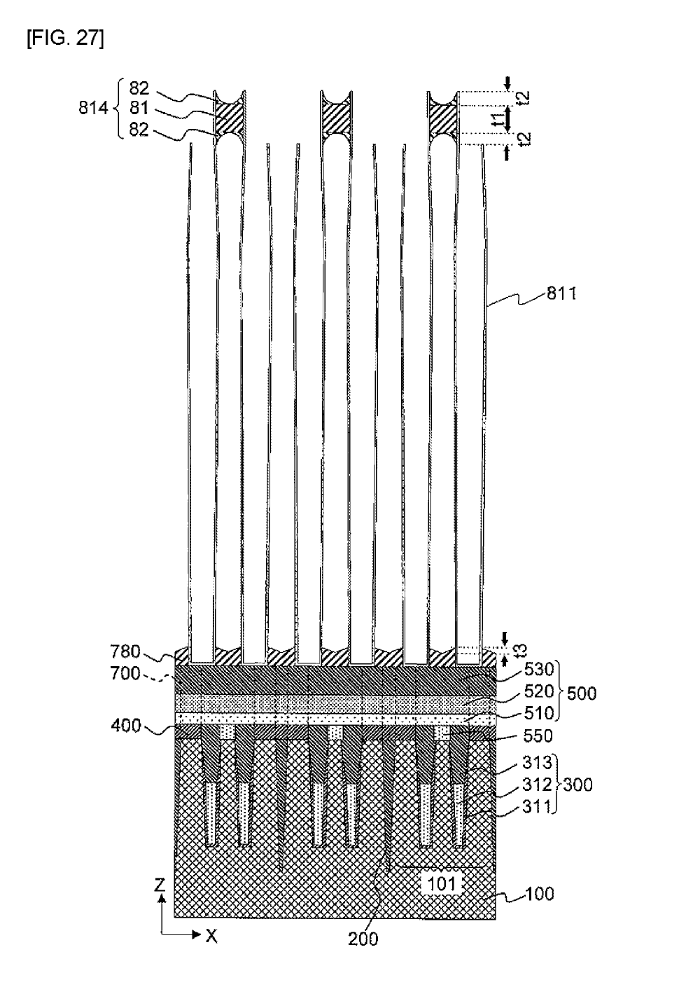

A method for manufacturing the semiconductor device 30 according to the present embodiment will be described next with reference to FIGS. 26 to 27.

The steps up to the formation of the second sacrificial oxide film 802 are first of all performed in the same way as in the first embodiment.

As illustrated in FIG. 26, the lower layer side SiN film B 82, the SiN film A 81, and the upper layer side SiN film B 82 which subsequently become the beams 814 are then formed in succession on the second sacrificial oxide film 802. The thickness of the SiN film A 81 is set to the thickness t1 required for the beams 814 after the oxide film wet etching. The film thicknesses of the lower layer side SiN film B 82 and the upper layer side SiN film B 82 are approximately the same t4 as the depth of the hollows formed by the subsequent oxide film wet etching. The film thicknesses t1 and t4 can be set respectively to 80 nm and 60 nm for example as described above.

The SiN film B 82 and the SiN film A 81 can be formed consecutively using a plasma CVD method. The formation of the SiN film B 82 can be achieved under the conditions of a temperature of 500 to 550° C., a chamber pressure of 3 to 5 Pa, and a source gas of 0 to 50 sccm of trimethyldisilane, 100 to 300 sccm of SiH₄, and 400 to 600 sccm of NH₃ in the same way as in the first embodiment. The SiN film A 81 has a higher trimethyldisilane flow rate under the above conditions. That is, the lower layer side SiN film B 82, the SiN film A 81, and the SiN film B 82 can be formed consecutively by switching the trimethyldisilane flow rate for each step during the series of film formation steps.

Next, a plasma TEOS film is formed as the fifth sacrificial oxide film 805 on the upper layer side SiN film B 82.

Following this, the lower electrodes 811 are formed using the same steps as in the first embodiment, after which oxide film wet etching is performed using hydrofluoric acid with a concentration of 50%, and the first and second sacrificial oxide films 801 and 802 are removed. The state at this time is illustrated in FIG. 27.

As illustrated in FIG. 27, the upper and lower surfaces of the SiN film B 82 are etched to produce a curved surface shape with the depth t2 (e.g., 5 to 7 nm) during the oxide film wet etching of the sacrificial oxide films. The film thickness of the SiN film A 81 substantially remains at t1 because the etching rate is lower even with exposure to the etching liquid and because the time of exposure to the etching liquid is short. Consequently, the thickness t1 required for the beams 814 can be maintained and the required strength can be ensured. The surface of the stopper film 780 is formed with hollows having the depth t3 in the same way as in the first embodiment because the stopper film 780 is exposed to the etching liquid from before the SiN film A 81 forming part of the beams 814 is exposed to the etching liquid (that is, while the SiN film B 82 that forms part of the beams 814 is exposed to the etching liquid).

The semiconductor device 30 illustrated in FIG. 23 is subsequently completed via the same steps as in the first embodiment.

As described above, in addition to the same effects as in the first and second embodiments, there is an effect in that control of the film thickness is facilitated and the strength is improved due to the three-layer structure of the beams 814 according to the present embodiment.

While several embodiments of the present invention have been described, the present invention is not limited to the above embodiments and various modifications and variations are allowed within the scope of the invention described in the claims. In particular, the film formation methods for the films and the source gases are merely examples and various film formation methods and starting materials may be used.

This application claims priority on the basis of Japanese Patent Application 2012-242314 filed on Nov. 2, 2012 and all disclosures thereof are incorporated herein.

### LIST OF REFERENCE NUMERALS

10, 20, 30 Semiconductor device
81 SiN film A
82 SiN film B
91 Resist mask
100 Semiconductor substrate
101 Active region
200 Element isolation region
300 Embedded word line
311 Gate insulating film
312 Gate metal
313 Cap insulating film
400 First interlayer insulating film
500 Bit line
510 First conductive film
520 Second conductive film
530 Cover film
550 Bit contact
600 Second interlayer insulating film
700 Capacitive contact
780 Stopper film
800 Capacitor
801 First sacrificial oxide film
802 Second sacrificial oxide film
803 Third sacrificial oxide film
804 Fourth sacrificial oxide film
805 Fifth sacrificial oxide film
810 Cylinder hole
811 Lower electrode
812 Capacitance insulating film
813 Upper electrode
814 Beam
815 Filler film
816 Adhesive film
817 Capacitance plate
900 Third interlayer insulating film
910 Wiring contact
920 Wiring
930 Protective insulating film

1. A semiconductor device manufacturing method comprising:
laminating a stopper film, a sacrificial film, and a beam constituent material film in succession on a semiconductor substrate;
forming a cylinder hole that penetrates the stopper film, the sacrificial film, and the beam constituent material film;
forming a lower electrode that covers an inner surface of the cylinder hole;
patterning the beam constituent material film so as to form a beam that is connected to at least a portion of the external circumferential surface of the lower electrode thereby, exposing a portion of the sacrificial film; and
removing the sacrificial film with wet etching and forming a hollow in the surface of the beam that is deeper than a hollow formed in the surface of the stopper film.

2. The method of claim 1, wherein the stopper film and the beam constituent material film are formed using the same starting materials, and the etching rate of an etching liquid used for the wet etching up to a prescribed depth from at least the upper and lower surfaces of the beam constituent material film, is faster than that of the stopper film.

3. The method of claim 2, wherein the etching rate for the upper and lower surfaces of the beam constituent material film is 1.2 to 3 times the etching rate for the stopper film.

4. The method of claim 2, wherein the stopper film and the beam constituent material film are both silicon nitride films.

5. The method of claim 4, wherein the stopper film and the beam constituent material film are formed with a plasma CVD method using trimethyldisilane, SiH₄, and NH₃ as source gases.

6. The method of claim 5, wherein the flow rates of the SiH₄ and the NH₃ when forming the beam constituent material film are the same as the respective flow rates of the SiH₄ and the NH₃ when forming the stopper film, and the flow rate of the trimethyldisilane for forming a layer up to a prescribed depth from at least the surface of the beam constituent material film, is less than the flow rate of the trimethyldisilane for forming the stopper film.

7. The method of claim 1, wherein the beam constituent material film is a single-layer film.

8. The method of claim 1, wherein the beam constituent material film is a three-layer structure film.

9. The method of claim 1, wherein patterning of the beam constituent material film is performed before forming the cylinder hole, and the lower electrode is connected to the beam thereafter due to the formation of the cylinder hole in such a way that a portion of the inner surface thereof is formed by the beam constituent material film.

10. The method of claim 1, wherein patterning of the beam constituent material film is performed so that the lower electrode is coupled to another lower electrode by the beam.

11. The method of claim 1, wherein a capacitance insulating film is further formed over the entire surface including an exposed surface of the lower electrode that is exposed by the removal of the sacrificial film, and an upper electrode is formed on the capacitance insulating film.

12. The method of claim 4, wherein the sacrificial film is a silicon oxide film.

13. The method of claim 1, wherein the sacrificial film is formed by laminating a plurality of films using different film formation methods.

14. A semiconductor device comprising:
a lower electrode having a lower end part, an upper end part, and an external circumferential surface continuous from the lower end part to the upper end part;
a stopper film connected to the external circumferential surface of the lower end part and formed with a hollow on the upper surface thereof; and
a beam connected to at least a portion of the external circumferential surface at a position remote from the lower end part, and having hollows connected on the upper surface and lower surface thereof;
wherein the depth of the hollows formed in the upper surface and lower surface of the beam is greater than the depth of the hollow formed in the upper surface of the stopper film.

15. The semiconductor device of claim 14, wherein the stopper film and the beam comprise the same material, and at least a portion of the upper surface and the lower surface of the beam has a different composition ratio than the stopper film.

16. The semiconductor device of claim 14, comprising:
a capacitance insulating film formed continuously from the external circumferential surface to the upper surface of the stopper film and to the upper surface and the lower surface of the beam; and
an upper electrode formed on the capacitance insulating film.

17. The semiconductor device of claim 14, wherein the beam couples the lower electrode with another lower electrode.
